(19) United States
(12) Patent Application Publication
(10) Pub. No.: US 2026/0025157 A1
(43) Pub. Date: Jan. 22, 2026

(54) Wireless Circuitry with a Hybrid Coupler

(71) Applicant: Apple Inc., Cupertino, CA (US)

(72) Inventors: Masoud Pashaeifar, Munich (DE); Yi Zhao, San Jose, CA (US)

(21) Appl. No.: 18/774,807

(22) Filed: Jul. 16, 2024

(51) Int. Cl. H04B 1/18; H01P 1/213; H03H 7/46; H04B 1/04

(52) U.S. Cl. CPC H04B 1/18; H01P 1/213; H03H 7/461; H04B 1/0458

(57) ABSTRACT

Wireless circuitry can be provided with a first amplifier and a hybrid coupler having a first port configured to receive a vertically polarized signal from an antenna, a second port configured to receive a horizontally polarized signal the antenna, and a third port coupled to an input of the first amplifier. The wireless circuitry can further include a second amplifier having an input coupled to a fourth port of the hybrid coupler, wherein the hybrid coupler comprises a quadrature hybrid coupler. The wireless circuitry can further include first circuits coupled to an output of the first amplifier and configured to produce first and second baseband signals, second circuits coupled to an output of the second amplifier and configured to produce third and fourth baseband signals, and processing circuitry configured to selectively combine the first and third baseband signals and selectively combine the second and fourth baseband signals.

### FIELD

This disclosure relates generally to electronic devices and, more particularly, to electronic devices with wireless communications circuitry.

### BACKGROUND

Electronic devices can be provided with wireless communications capabilities. An electronic device with wireless communications capabilities has wireless circuitry with one or more antennas. A transceiver in the wireless circuitry uses the antennas to transmit and receive radio-frequency signals. It can be challenging to design satisfactory wireless circuitry for an electronic device.

### SUMMARY

An aspect of the disclosure provides circuitry that includes a first radio-frequency amplifier and a hybrid coupler having a first port configured to receive a vertically polarized signal from an antenna, a second port configured to receive a horizontally polarized signal the antenna, and a third port coupled to the first radio-frequency amplifier. The circuitry can optionally further include one or more of: a second radio-frequency amplifier coupled to a fourth port of the hybrid coupler, where the hybrid coupler is a quadrature hybrid coupler, a downconversion circuit coupled between the antenna and the first and second ports of the hybrid coupler, a first quadrature demodulator coupled to the first radio-frequency amplifier, a second quadrature demodulator coupled to the second radio-frequency amplifier, a first mixer configured to receive a first amplified signal from the first radio-frequency amplifier and a first oscillating signal, a second mixer configured to receive the first amplified signal from the first radio-frequency amplifier and a second oscillating signal different than the first oscillating signal, a third mixer configured to receive a second amplified signal from the second radio-frequency amplifier and the second oscillating signal, a fourth mixer configured to receive the second amplified signal from the second radio-frequency amplifier and the first oscillating signal, a first data converter configured to receive a first analog baseband signal from the first mixer, a second data converter configured to receive a second analog baseband signal from the second mixer, a third data converter configured to receive a third analog baseband signal from the third mixer, and a fourth data converter configured to receive a fourth analog baseband signal from the fourth mixer. The hybrid coupler can be configured to orthogonally combine the vertically polarized signal and the horizontally polarized signal.

An aspect of the disclosure provides a method of operating wireless circuitry that includes receiving vertically polarized radio-frequency signals at a first port of a hybrid coupler, receiving horizontally polarized radio-frequency signals at a second port of the hybrid coupler, outputting, at a third port of the hybrid coupler, signals to a first radio-frequency amplifier, and outputting, at a fourth port of the hybrid coupler, signals to a second radio-frequency amplifier. The method can further include using a downconverter to downconvert the vertically polarized radio-frequency signals prior to feeding the vertically polarized radio-frequency signals to the first port of the hybrid coupler and to downconvert the horizontally polarized radio-frequency signals prior to feeding the horizontally polarized radio-frequency signals to the second port of the hybrid coupler. The method can further include using one or more demodulators to receive signals from the radio-frequency amplifiers and to output corresponding analog baseband signals. The method can further include using one or more data converts to receive the analog baseband signals and output corresponding digital baseband signals. The method can further include selectively combining the digital baseband signals by computing differences and sums.

An aspect of the disclosure provides circuitry that includes a first amplifier and a hybrid coupler having a first port configured to convey radio-frequency signals of a first polarization orientation, a second port configured to convey radio-frequency signals of a second polarization orientation different than the first polarization orientation, and a third port coupled to the first amplifier. The circuitry can optionally further include a second amplifier coupled to a fourth port of the hybrid coupler, where the second polarization orientation is orthogonal to the first polarization orientation. The circuitry can further include first circuits coupled to an output of the first amplifier and configured to produce first and second baseband signals, second circuits coupled to an output of the second amplifier and configured to produce third and fourth baseband signals, and processing circuitry configured to selectively combine the first and third baseband signals and selectively combine the second and fourth baseband signals.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having transmit and receive circuitry in accordance with some embodiments.

FIG. 3 is a diagram showing an antenna coupled to multiple amplifiers via a hybrid coupler in accordance with some embodiments.

FIG. 4 is a diagram showing relevant signals produced by various components within the wireless circuitry of FIG. 3 in accordance with some embodiments.

FIG. 5 is a flow chart of illustrative steps for operating wireless circuitry of the type shown in FIGS. 1-4 in accordance with some embodiments.

### DETAILED DESCRIPTION

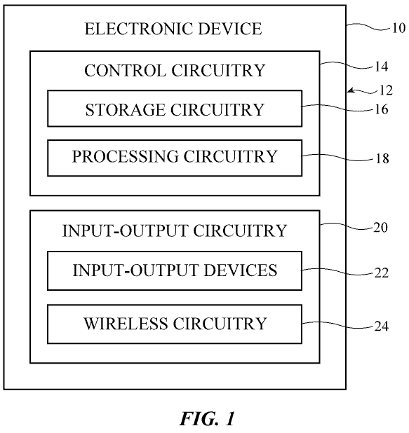

An electronic device such as device 10 of FIG. 1 may be provided with wireless circuitry having a hybrid coupler as described below. The wireless circuitry may include one or more antennas, at least first and second amplifiers, a hybrid coupler coupled between the one or more antennas and the first and second amplifiers, demodulators coupled the amplifiers, and data converters coupled to the demodulators. The hybrid coupler may have a first terminal configured to convey vertically polarized signals to/from an antenna, a second (isolation) terminal configured to convey horizontally polarized signals to/from the antenna, a third terminal coupled to the first amplifier, and a fourth terminal coupled to the second amplifier.

The demodulators can include a first demodulator coupled to the first amplifier and configured to output first and second baseband signals. The demodulators can further include a second demodulator coupled to the second amplifier and configured to output third and fourth baseband signals. The first, second, third, and fourth baseband signals can be converted by the data converters and selectively combined to obtain a vertically polarized in-phase (I) baseband signal, a vertically polarized quadrature (Q) baseband signal, a horizontally polarized quadrature baseband signal, and a horizontally polarized in-phase signal.

Such type of wireless architecture is sometimes referred to as a double quadrature transceiver with a balanced front end (or dual amplifier stage). Wireless circuitry configured in this way is technically advantageous and beneficial to minimize IQ mismatch without increasing the number of mixers in the demodulators. The balanced amplifier stage can further provide wideband input matching while also providing midband output matching. Input matching is also not required for the amplifiers, which can lead to power and area savings. Such double quadrature transceiver with balanced front end can be adopted for a receive (RX) path and/or a transmit (TX) path.

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols-sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHZ), and/or other Wi-Fi® bands (e.g., from 1875-5160 MHZ), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), other centimeter or millimeter wave frequency bands between 10-300 GHz, near-field communications frequency bands (e.g., at 13.56 MHZ), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

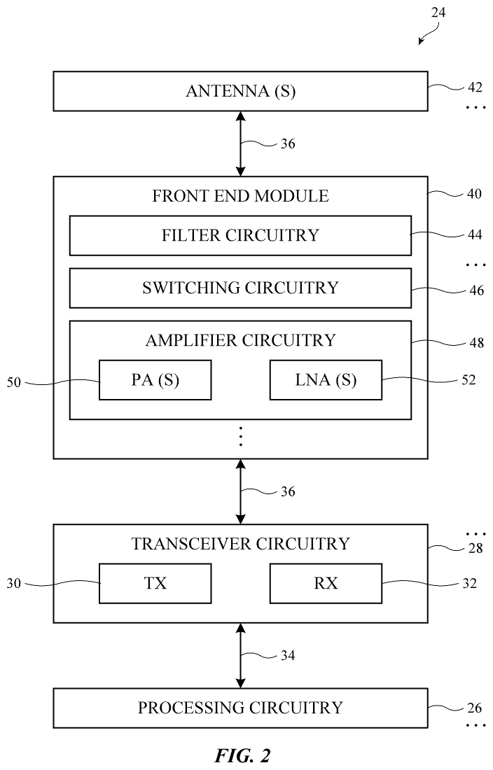

FIG. 2 is a diagram showing illustrative components within wireless circuitry 24. As shown in FIG. 2, wireless circuitry 24 may include processing circuitry such as processing circuitry 26, radio-frequency (RF) transceiver circuitry such as radio-frequency transceiver 28, radio-frequency front end circuitry such as radio-frequency front end module (FEM) 40, and antenna(s) 42. Processing circuitry 26 may include one or more baseband processor, application processor, general purpose processor, microprocessor, microcontroller, digital signal processor, host processor, application specific signal processing hardware, and/or other type of processor. Processing circuitry 26 may be coupled to transceiver 28 over path 34. Transceiver 28 may be coupled to antenna 42 via radio-frequency transmission line path 36. Radio-frequency front end module 40 may be disposed on radio-frequency transmission line path 36 between transceiver 28 and antenna 42.

In the example of FIG. 2, wireless circuitry 24 is illustrated as including only a single processor 26, a single transceiver 28, a single front end module 40, and a single antenna 42 for the sake of clarity. In general, wireless circuitry 24 may include any desired number of processors 26, any desired number of transceivers 28, any desired number of front end modules 40, and any desired number of antennas 42. Each processor 26 may be coupled to one or more transceiver 28 over respective paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is merely illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processing circuitry 26 may provide transmit signals (e.g., digital or baseband signals) to transceiver 28 over path 34. Transceiver 28 may further include circuitry for converting the transmit (baseband) signals received from processing circuitry 26 into corresponding radio-frequency signals. For example, transceiver circuitry 28 may include mixer circuitry for up-converting (or modulating) the transmit (baseband) signals to radio frequencies prior to transmission over antenna 42. The example of FIG. 2 in which processing circuitry 26 communicates with transceiver 28 is merely illustrative. In general, transceiver 28 may communicate with a baseband processor, an application processor, general purpose processor, a microcontroller, a microprocessor, or one or more processors within circuitry 18. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front end module 40. Antenna 42 may transmit the radio-frequency signals to external wireless equipment by radiating the radio-frequency signals into free space.

In performing wireless reception, antenna 42 may receive radio-frequency signals from the external wireless equipment. The received radio-frequency signals may be conveyed to transceiver 28 via radio-frequency transmission line path 36 and front end module 40. Transceiver 28 may include circuitry such as receiver (RX) 32 for receiving signals from front end module 40 and for converting the received radio-frequency signals into corresponding baseband signals. For example, transceiver 28 may include mixer circuitry for down-converting (or demodulating) the received radio-frequency signals to baseband frequencies prior to conveying the received signals to processor 26 over path 34.

Front end module (FEM) 40 may include radio-frequency front end circuitry that operates on the radio-frequency signals conveyed (transmitted and/or received) over radio-frequency transmission line path 36. FEM 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier circuits 50 and/or one or more low-noise amplifier circuits 52), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip. If desired, amplifier circuitry 48 and/or other components in front end 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front end module 40. For example, transceiver 28 may be formed on another substrate such as the main logic board of device 10, a rigid printed circuit board, or flexible printed circuit that is not a part of front end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processor 26 and/or portions of transceiver 28 (e.g., a host processor on transceiver 28) may form a part of control circuitry 14. Control circuitry 14 (e.g., portions of control circuitry 14 formed on processor 26, portions of control circuitry 14 formed on transceiver 28, and/or portions of control circuitry 14 that are separate from wireless circuitry 24) may provide control signals (e.g., over one or more control paths in device 10) that control the operation of front end module 40.

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHZ), and/or other Wi-Fi® bands (e.g., from 1875-5160 MHZ), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near-field communications bands (e.g., at 13.56 MHZ), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

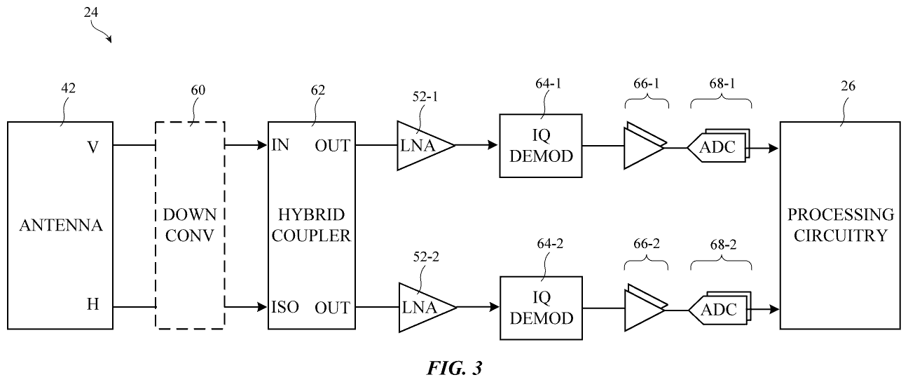

FIG. 3 is a diagram of illustrative wireless circuitry 24 having one or more antenna(s) 42 coupled to circuitry in a receive (RX) path. As shown in FIG. 3, antenna 42 can represent any type of antenna (e.g., a patch antenna) having a first antenna feed configured to convey vertically (V) polarized signals and having a second antenna feed configured to convey horizontally (H) polarized signals. The vertically polarized signals and the horizontally polarized signals have different (e.g., orthogonal) polarization orientations. The circuitry in the receive path can include one or more amplifiers such as radio-frequency amplifiers 52-1 and 52-2, one or more demodulation circuits such as demodulators 64-1 and 64-2, additional amplification circuits such as amplifiers 66-1 and 66-2, and data conversion circuits such as data converters 68-1 and 68-2. Amplifiers 52-1 and 52-2 in the receive path can represent low noise amplifiers (LNAs), as an example.

A downconversion circuit such as downconverter 60 can optionally be coupled between antenna 42 and amplifiers 52-1 and 52-2. Downconverter 60 can be configured to convert the vertically polarized and horizontally polarized signals from a radio frequency (RF) to relatively lower frequencies such as an intermediate frequency (IF). In general, an intermediate frequency can refer to a frequency between radio frequencies used for wireless transmission and baseband frequencies used for digital processing. Shifting signals to an intermediate frequency during radio reception or transmission can help simplify filtering and amplification operations to help enhance the overall performance of wireless circuitry 24.

First amplifier 52-1 can output amplified signals to a first demodulator 64-1 such as a first IQ demodulator, also referred to as a quadrature demodulator. A quadrature demodulator can refer to and be defined herein as a demodulator that modulates an incoming signal using two carrier (oscillating) waves that are 90 degrees out of phase with each other (e.g., e.g., LO signals LOq and LOi). The first quadrature demodulator 64-1 can be configured to convert the amplified signals from a radio frequency or intermediate frequency into its corresponding baseband in-phase (I) and quadrature (Q) components. The in-phase component is “in phase” or temporally aligned with the original carrier signal, whereas the quadrature component is 90 degrees out of phase with or temporally offset from the original carrier signal. The baseband I and Q components output from the first quadrature demodulator 64-1 can be amplified by one or more optional amplifier stages 66-1 and then converted into corresponding digital signals using one or more analog-to-digital converters (ADC) 68-1. The digital signals output from ADC(s) 68-1 can then be conveyed to processing circuitry 26 for additional processing.

Second amplifier 52-2 can output amplified signals to a second demodulator 64-2 such as a second IQ (quadrature) demodulator. The second quadrature demodulator 64-2 can be configured to convert the amplified signals from a radio frequency or intermediate frequency into its corresponding baseband in-phase (I) and quadrature (Q) components. The baseband I and Q components output from the second quadrature demodulator 64-2 can be amplified by one or more optional amplifier stages 66-2 and then converted into corresponding digital signals using one or more analog-to-digital converters (ADC) 68-2. The digital signals output from ADC(s) 68-2 can then be conveyed to processing circuitry 26 for additional processing.

In accordance with an embodiment, wireless circuitry 24 can be provided with a hybrid coupling circuit such as hybrid coupler 62 interposed between antenna 42 and amplifiers 52 (e.g., amplifiers 52-1 and 52-2). As shown in FIG. 3, hybrid coupler 62 may be a passive device with at least four ports configured to combine or split high-frequency signals. For example, hybrid coupler 62 can be configured to split one or more input signals into two corresponding output signals that are 90 degrees out of phase with one another. Such type of hybrid coupler 62 is sometimes referred to and defined herein as a 90 degree hybrid coupler or a quadrature hybrid coupler.

In the embodiment of FIG. 3, hybrid coupler 62 may have a first (input) port configured to receive the vertically polarized signals from antenna 42 (e.g., optionally downconverted by circuit 60), a second (isolation) port configured to receive the horizontally polarized signals from antenna 42 (e.g., optionally downconverted by circuit 60), a third port coupled to an input of first amplifier 52-1, and a fourth port coupled to an input of second amplifier 52-2. The third and fourth ports of hybrid coupler 62 are sometimes considered first and second “output” ports of hybrid coupler 62. Configured in this way, the horizontally and vertically polarized signals can be combined orthogonally using hybrid coupler 62. The example of FIG. 3 in which the vertically polarized signals are being fed to the first input (IN) port of hybrid coupler 62 while the horizontally polarized signals are being fed to the second isolation (ISO) port of hybrid coupler 62 is illustrative. In other embodiments, the vertically polarized signals can be fed to the second isolation (ISO) port of hybrid coupler 62 while the horizontally polarized signals are fed to the first input (IN) port of hybrid coupler 62. The isolation port of hybrid coupler 62 can also sometimes be referred to as an input port.

Such type of wireless architecture having hybrid coupler 62 with two (input) ports coupled to separate H and V antenna feeds and two (output) ports coupled to two different amplifiers 52 is sometimes referred to herein as a combined horizontal and vertical double quadrature transceiver topology with a balanced front end. This type of wireless architecture can help ensure that the I and Q components of both the horizontally and vertically polarized signals appear across the various baseband signals, which can then be combined in the digital domain using simple addition or subtraction operations. Operating wireless circuitry 24 in this way can be technically advantageous and beneficial to reduce potential IQ mismatch. Having hybrid coupler 62 at the input of amplifiers 52 can also help ensure broadband impedance matching. Arranged in this way, the input matching between the two amplifiers 52 is not required, which can lead to power and area savings.

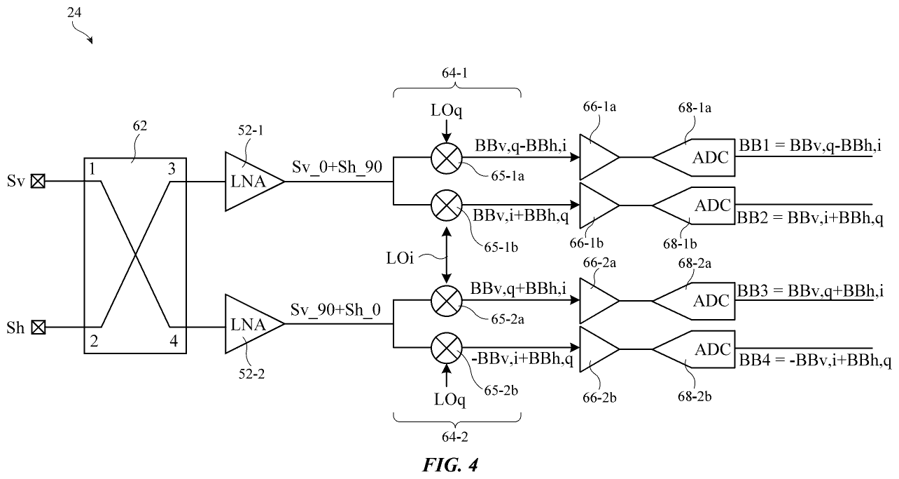

FIG. 4 is a diagram showing relevant signals produced by the various components within wireless circuitry 24 of the type described in connection with FIG. 3. As shown in FIG. 4, hybrid coupler 62 may have a first (1) port configured to receive vertically polarized radio-frequency signals Sv from an antenna, a second (2) port configured to receive horizontally polarized radio-frequency signals Sh from the antenna, a third (3) port coupled to the input of amplifier 52-1, and a fourth (4) port coupled to the input of amplifier 52-2. The first and second ports of hybrid coupler 62 may be referred to as input ports, input and isolation ports, respectively, or isolation and input ports, respectively. The third and fourth ports of hybrid coupler 62 may be referred to as output ports.

Arranged in this way, first amplifier 52-1 may be configured to output a corresponding amplified signal having signal components Sv_0 and Sh_90, where signal Sv_0 represents a vertically polarized signal that is “in phase” with Sv and where signal Sh_90 represents horizontally polarized signal that is 90 degrees “out of phase” with Sh.

These two signal components Sv_0 and Sh_90 can then be conveyed to first quadrature demodulator 64-1. The first quadrature demodulator 64-1 can include a first mixer 65-1a and a second mixer 65-1b. The first mixer 65-1a can receive signals Sv_0 and Sh_90 from amplifier 52-1 and also an oscillating signal LOq to produce a corresponding baseband signal equal to a difference between analog signals BBv,q and BBh,i (e.g., the output of mixer 65-1a is equal to BBv,q-BBh,i), where BBv,q represents a vertically polarized quadrature baseband signal and where BBh,i represents a horizontally polarized in-phase baseband signal. Signal LOq may be output by a local oscillator (LO) and is thus sometimes referred to as an LO signal. The baseband signal output from mixer 65-1a can optionally be amplified by circuit 66-1a (e.g., one or more transimpedance amplifier stages or other types of amplifier stages) and converted into a digital signal using one or more data converter(s) 68-1a to produce a first digital baseband signal BB1 that is equivalent to a digital version of BBv,q minus BBh,i.

These two signal components Sv_0 and Sh_90 can also be conveyed to second mixer 65-1b of quadrature demodulator 64-1. The second mixer 65-1b can receive signals Sv_0 and Sh_90 from amplifier 52-1 and also an oscillating signal LOi to produce a corresponding baseband signal equal to a sum of analog signals BBv,i and BBh,q (e.g., the output of mixer 65-1b is equal to BBv,i+BBh,q), where BBv,i represents a vertically polarized in-phase baseband signal and where BBh,q represents a horizontally polarized quadrature baseband signal. Signal LOi may be 90 degrees out of phase with respect to LOq, may be output by a local oscillator (LO) and is thus sometimes also referred to as an LO signal. The baseband signal output from mixer 65-1b can optionally be amplified by circuit 66-1b (e.g., one or more transimpedance amplifier stages or other types of amplifier stages) and converted into a digital signal using one or more data converter(s) 68-1b to produce a second digital baseband signal BB2 that is equivalent to a digital version of BBv,i plus BBh,q.

At the other output port of hybrid coupler 62, amplifier 52-2 may be configured to output a corresponding amplified signal having signal components Sv_90 and Sh_0, where signal Sv_90 represents a vertically polarized signal that is 90 degrees out of phase with Sv and where signal Sh_0 represents horizontally polarized signal that is in phase with Sh. These two signal components Sv_90 and Sh_0 can then be conveyed to second quadrature demodulator 64-2. The second quadrature demodulator 64-2 can include a third mixer 65-2a and a fourth mixer 65-2b. The third mixer 65-2a can receive signals Sv_90 and Sh_0 from amplifier 52-2 and also an oscillating signal LOi to produce a corresponding baseband signal equal to a sum of analog signals BBv,q and BBh,i (e.g., the output of mixer 65-2a is equal to BBv,q+BBh,i). The baseband signal output from mixer 65-2a can optionally be amplified by circuit 66-2a (e.g., one or more transimpedance amplifier stages or other types of amplifier stages) and converted into a corresponding digital signal using one or more data converter(s) 68-2a to produce a third digital baseband signal BB3 that is equivalent to a digital version of BBv,q plus BBh,i.

The two signal components Sv_90 and Sh_0 output from amplifier 52-2 can also be conveyed to the fourth mixer 65-2b of quadrature demodulator 64-2. The fourth mixer 65-2b can receive signals Sv_90 and Sh_0 from amplifier 52-2 and also oscillating signal LOq to produce a corresponding baseband signal equal to a sum of analog signals-BBv,i and BBh,q (e.g., the output of mixer 65-2b is equal to −BBv,i+BBh,q). The baseband signal output from mixer 65-2b can optionally be amplified by circuit 66-2b (e.g., one or more transimpedance amplifier stages or other types of amplifier stages) and converted into a digital signal using one or more data converter(s) 68-2b to produce a fourth digital baseband signal BB4 that is equivalent to a digital version of negative BBv,i plus BBh,q. Baseband signal BB4 can also be rewritten as (BBh,q-BBv,i).

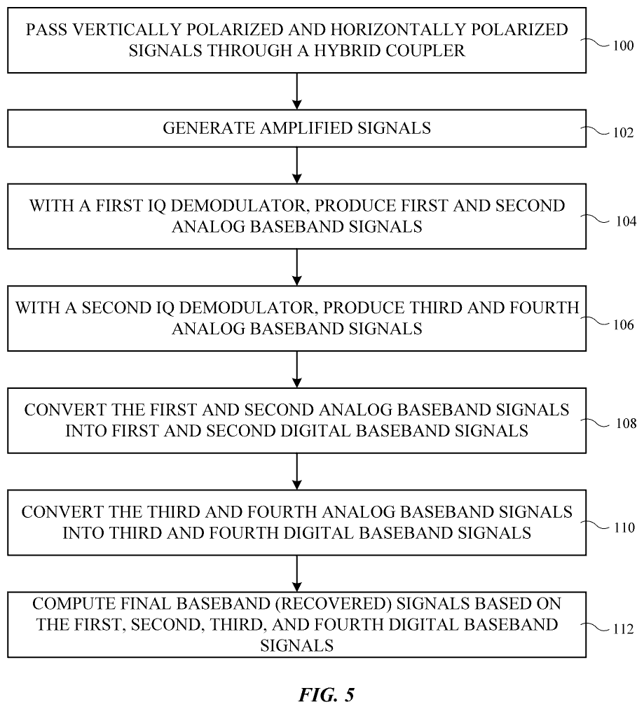

The digital baseband signals BB1, BB2, BB3, and BB4 generated in this way can be selectively combined by processing circuitry (see, e.g., circuitry 26 in FIGS. 2 and 3) using simple addition or subtraction operations. FIG. 5 is a flow chart of illustrative steps for operating wireless circuitry 24 of the type described in connection with FIGS. 1-4. During the operations of block 100, vertically polarized and horizontally polarized radio-frequency signals can be conveyed from one or more antenna(s) 42 to hybrid coupler 62. For example, horizontally polarized signals Sv (see FIG. 4) can be conveyed to a first (input or isolation) port of hybrid coupler 62 while vertically polarized signal Sh can be conveyed to a second (isolation or input) port of hybrid coupler 62.

During the operations of block 102, wireless circuitry 24 can be configured to generate corresponding amplified signals using amplifiers 52-1 and 52-2. Amplifier 52-1 may have an input coupled to the third (output) port of hybrid coupler 62, whereas amplifier 52-2 may have an input coupled to the fourth (output) port of hybrid coupler 62. Arranged as such, first amplifier 52-1 may be configured to output amplified signals Sv_0+Sh_90, whereas second amplifier 52-2 may be configured to output amplified signals Vs_90+Sh_0.

During the operations of block 104, first demodulator 64-1 may be configured to produce first and second analog baseband signals. As shown in FIG. 4, the first mixer 65-1a of demodulator 64-1 may output a first analog baseband signal (BBv,q-BBh,i), whereas the second mixer 65-1b of demodulator 64-1 may output a second analog baseband signal (BBv,i+BBh,q). The first analog baseband signal may optionally be passed through one or more amplifier stages 66-1a. The second analog baseband signal may optionally be passed through one or more amplifier stages 66-1b.

During the operations of block 106, second demodulator 64-2 may be configured to produce third and fourth analog baseband signals. As shown in FIG. 4, the third mixer 65-2a of demodulator 64-2 may output a third analog baseband signal (BBv,q+BBh,i), whereas the fourth mixer 65-2b of demodulator 64-2 may output a fourth analog baseband signal (−BBv,i+BBh,q). The third analog baseband signal may optionally be passed through one or more amplifier stages 66-2a. The fourth analog baseband signal may optionally be passed through one or more amplifier stages 66-2b. Although the operations of block 106 are shown as occurring after block 104, the operations of block 106 can alternatively occur in parallel (simultaneously) with or before the operations of block 104.

During the operations of block 108, the first and second analog baseband signals may be converted into corresponding first and second digital baseband signals (e.g., BB1 and BB2) using data converters 68-1a and 68-1b. During the operations of block 110, the third and fourth analog baseband signals may be converted into corresponding third and fourth digital baseband signals (BB3 and BB4) using data converters 68-2a and 68-2b. Although the operations of block 110 are shown as occurring after block 108, the operations of block 110 can alternatively occur in parallel (simultaneously) with or before the operations of block 108.

The first, second, third, and fourth digital baseband signals may be conveyed to processing circuitry 26. During the operations of block 112, processing circuitry 26 can be configured to compute final baseband signals based on the first, second, third and fourth digital baseband signals. For example, a difference between BB2 and BB4 (e.g., BB2−BB4) can be computed by processing circuitry 26 to produce 2*BBv,i to recover the original vertically polarized in-phase signal. As another example, a sum of BB1 and BB3 (e.g., BB1+BB3) can be computed by processing circuitry 26 to produce 2*BBv,q to recover the original vertically polarized quadrature signal. As another example, a sum of BB2 and BB4 (e.g., BB2+BB4) can be computed by processing circuitry 26 to produce 2*BBh,q to recover the original horizontally polarized quadrature signal. As another example, a sum of negative BB1 and BB3 (e.g., −BB1+BB3, which is equal to a difference between BB1 and BB3) can be computed by processing circuitry 26 to produce 2*BBh,i to recover the original horizontally polarized in-phase signal. Final baseband signals recovered in this way can exhibit reduced IQ mismatch.

The operations of FIG. 5 are illustrative. In some embodiments, one or more of the described operations may be modified, replaced, or omitted. In some embodiments, one or more of the described operations may be performed in parallel. In some embodiments, additional processes may be added or inserted between the described operations. If desired, the order of certain operations may be reversed or altered and/or the timing of the described operations may be adjusted so that they occur at slightly different times. In some embodiments, the described operations may be distributed in a larger system.

Although the embodiments of FIGS. 3-5 are directed to a combined horizontal and vertical double quadrature transceiver topology with a balanced front end for a wireless receive path, the present embodiments can alternatively or additionally be adapted to a wireless transmit path. In the transmit path, the hybrid coupler may have output ports coupled to horizontally and vertically polarized feeds of one or more antennas 42 and input ports coupled to at least two separate power amplifiers (see, e.g., radio-frequency transmitting amplifiers 50 in FIG. 2).

The methods and operations described above in connection with FIGS. 1-5 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The foregoing is merely illustrative and various modifications can be made to the described embodiments. The foregoing embodiments may be implemented individually or in any combination.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

What is claimed is:

1. Circuitry comprising:
a first radio-frequency amplifier; and
a hybrid coupler having a first port configured to receive a vertically polarized signal from an antenna, a second port configured to receive a horizontally polarized signal the antenna, and a third port coupled to the first radio-frequency amplifier.

2. The circuitry of claim 1, further comprising:
a second radio-frequency amplifier coupled to a fourth port of the hybrid coupler, wherein the hybrid coupler comprises a quadrature hybrid coupler.

3. The circuitry of claim 2, further comprising:
a downconversion circuit coupled between the antenna and the first and second ports of the hybrid coupler.

4. The circuitry of claim 2, further comprising:
a first quadrature demodulator coupled to the first radio-frequency amplifier; and
a second quadrature demodulator coupled to the second radio-frequency amplifier.

5. The circuitry of claim 4, wherein the first quadrature demodulator comprises:
a first mixer configured to receive a first amplified signal from the first radio-frequency amplifier and a first oscillating signal; and
a second mixer configured to receive the first amplified signal from the first radio-frequency amplifier and a second oscillating signal different than the first oscillating signal.

6. The circuitry of claim 5, wherein the second quadrature demodulator comprises:
a third mixer configured to receive a second amplified signal from the second radio-frequency amplifier and the second oscillating signal; and
a fourth mixer configured to receive the second amplified signal from the second radio-frequency amplifier and the first oscillating signal.

7. The circuitry of claim 6, further comprising:
a first data converter configured to receive a first analog baseband signal from the first mixer;
a second data converter configured to receive a second analog baseband signal from the second mixer;
a third data converter configured to receive a third analog baseband signal from the third mixer; and
a fourth data converter configured to receive a fourth analog baseband signal from the fourth mixer.

8. The circuitry of claim 7, further comprising:
one or more first amplifier stages coupled between the first mixer and the first data converter;
one or more second amplifier stages coupled between the second mixer and the second data converter;
one or more third amplifier stages coupled between the third mixer and the third data converter; and
one or more fourth amplifier stages coupled between the fourth mixer and the fourth data converter.

9. The circuitry of claim 7, further comprising:
processing circuitry configured to receive a first digital baseband signal from the first data converter, a second digital baseband signal from the second data converter, a third digital baseband signal from the third data converter, and a fourth digital baseband signal from the fourth data converter and further configured to selectively combine the first, second, third and fourth digital baseband signals.

10. The circuitry of claim 9, wherein the processing circuitry is further configured to:
compute a difference between the second and fourth digital baseband signals;
compute a sum of the second and fourth digital baseband signals;
compute a sum of the first and third digital baseband signals; and
compute a difference between the first and third digital baseband signals.

11. The circuitry of claim 1, wherein the hybrid coupler is configured to orthogonally combine the vertically polarized signal and the horizontally polarized signal.

12. A method of operating wireless circuitry, comprising:
receiving vertically polarized radio-frequency signals at a first port of a hybrid coupler;
receiving horizontally polarized radio-frequency signals at a second port of the hybrid coupler;
outputting, at a third port of the hybrid coupler, signals to a first radio-frequency amplifier; and
outputting, at a fourth port of the hybrid coupler, signals to a second radio-frequency amplifier.

13. The method of claim 12, further comprising:
with a downconverter, downconverting the vertically polarized radio-frequency signals prior to feeding the vertically polarized radio-frequency signals to the first port of the hybrid coupler and downconverting the horizontally polarized radio-frequency signals prior to feeding the horizontally polarized radio-frequency signals to the second port of the hybrid coupler.

14. The method of claim 12, further comprising:
with a first demodulator coupled to an output of the first radio-frequency amplifier, outputting first and second analog baseband signals;
with a second demodulator coupled to an output of the second radio-frequency amplifier, outputting third and fourth analog baseband signals.

15. The method of claim 14, further comprising:
with a first data converter, receiving the first analog baseband signal and outputting a corresponding first digital baseband signal;
with a second data converter, receiving the second analog baseband signal and outputting a corresponding second digital baseband signal;
with a third data converter, receiving the third analog baseband signal and outputting a corresponding third digital baseband signal; and
with a fourth data converter, receiving the fourth analog baseband signal and outputting a corresponding fourth digital baseband signal.

16. The method of claim 15, further comprising:
selectively combining the second and fourth digital baseband signals; and
selectively combining the first and third digital baseband signals.

17. The method of claim 16, wherein:
selectively combining the second and fourth digital baseband signals comprises computing a difference between the second and fourth digital baseband signals and computing a sum of the second and fourth digital baseband signals; and
selectively combining the first and third digital baseband signals comprises computing a sum of the first and third digital baseband signals and computing a difference between the first and third digital baseband signals.

18. Circuitry comprising:
a first amplifier; and
a hybrid coupler having a first port configured to convey radio-frequency signals of a first polarization orientation, a second port configured to convey radio-frequency signals of a second polarization orientation different than the first polarization orientation, and a third port coupled to the first amplifier.

19. The circuitry of claim 18, further comprising:
a second amplifier coupled to a fourth port of the hybrid coupler, wherein the second polarization orientation is orthogonal to the first polarization orientation.

20. The circuitry of claim 19, further comprising:
first circuits coupled to an output of the first amplifier and configured to produce first and second baseband signals;
second circuits coupled to an output of the second amplifier and configured to produce third and fourth baseband signals; and
processing circuitry configured to selectively combine the first and third baseband signals and selectively combine the second and fourth baseband signals.
